(19) United States
(12) Patent Application Publication
(10) Pub. No.: US 2026/0040940 A1
(43) Pub. Date: Feb. 5, 2026

(54) SEMICONDUCTOR DEVICE HAVING AIR GAP AND METHOD FOR MANUFACTURING THE SAME

(71) Applicant: TAIWAN SEMICONDUCTOR MANUFACTURING COMPANY, LTD., Hsinchu (TW)

(72) Inventors: Tzu-Hui Wei, Hsinchu (TW); Wei-Hao LIAO, Hsinchu (TW)

(73) Assignee: TAIWAN SEMICONDUCTOR MANUFACTURING COMPANY, LTD., Hsinchu (TW)

(21) Appl. No.: 18/790,330

(22) Filed: Jul. 31, 2024

(51) Int. Cl. H01L 21/768; H01L 21/02; H01L 21/311

(52) U.S. Cl. CPC H01L 21/7682; H01L 21/02211; H01L 21/31116; H01L 21/31144; H01L 21/76834

(57) ABSTRACT

A method for manufacturing a semiconductor device includes: forming conductive interconnects spaced apart from each other and protruding upwardly from an upper surface of a dielectric layer, so as to form trenches among the conductive interconnects; forming functionalized molecules such that functionalized molecules are bonded to the upper surface of the dielectric layer so as to form a self-assembled monolayer filled in the trenches; subjecting the functionalized molecules to a rearrangement treatment so as to permit the functionalized molecules to be evenly bonded on the upper surface of the dielectric layer; forming an etch stop layer on the conductive interconnects and the self-assembled monolayer; and removing the self-assembled monolayer to form air gaps so that two adjacent ones of the conductive interconnects are spaced apart from each other by a corresponding one of the air gaps.

### BACKGROUND

With rapid development of semiconductor manufacturing technology, continual reduction in minimum feature sizes is a trend in the semiconductor industry. As the feature sizes in an integrated circuit (IC) chip are decreased, the distance between interconnect metal features (e.g., metal lines) is continually reduced in advanced nodes, which might induce resistance-capacitance (RC) delay and electronic signal interference. Therefore, the semiconductor industry strives to reduce the RC delay and the electronic signal interference of the IC chip so as to further improve chip performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 10 are schematic views illustrating some intermediate stages of the method as depicted in FIG. 1 in accordance with some embodiments.

FIG. 11 is a flow diagram illustrating a method for manufacturing a semiconductor device in accordance with some embodiments.

FIGS. 12 to 20 are schematic views illustrating some intermediate stages of the method as depicted in FIG. 11 in accordance with some embodiments.

FIGS. 21 to 26 are schematic views illustrating some intermediate stages of the method as depicted in FIG. 11 in accordance with some other embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “bottom,” “upper,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

With rapid development of semiconductor manufacturing technology, continual reduction in minimum feature sizes is a trend in the semiconductor industry. As the feature sizes in an integrated circuit (IC) chip are decreased, the distance between interconnect metal features (e.g., metal lines) is continually reduced in advanced nodes, and the resulting parasitic capacitance between the interconnect metal features increases, leading to higher power consumption and larger resistance-capacitance (RC) delay for the IC chip. In a current method for manufacturing the semiconductor device, after formation of the metal lines, a sacrificial material (for example, a molecular material containing carbon, hydrogen, and oxygen without a bonding head group) used for formation of air gaps among the metal lines is deposited to fill trenches formed among the metal lines. When widths of the trenches are different, a deposition height of the sacrificial material in an area where the width of the trenches is relatively large is lower than that of the sacrificial material in an area where the width of the trenches is relatively small. The greater the height difference of the sacrificial material is, the higher the air gap loading is. In addition, an etching-back process is required after the sacrificial material is filled into the trenches, so as to permit the sacrificial material in the trenches to have an identical height. However, the metal lines may be damaged by the etching-back process, resulting in increased resistance. Moreover, the height of the sacrificial material after the etching-back process is usually lower than the height of the metal lines. Therefore, air gaps formed after the sacrificial material is removed have a height lower than that of the metal lines, and thus, the capacitance between the metal lines cannot be reduced satisfactorily by the air gaps.

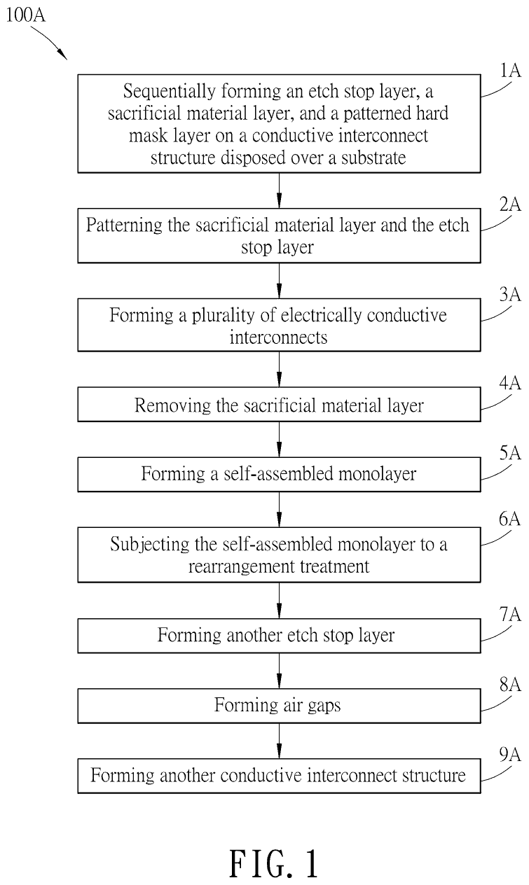

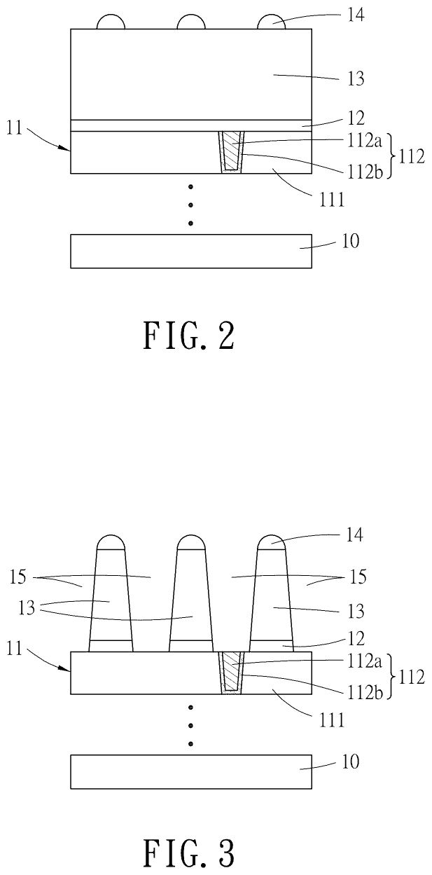

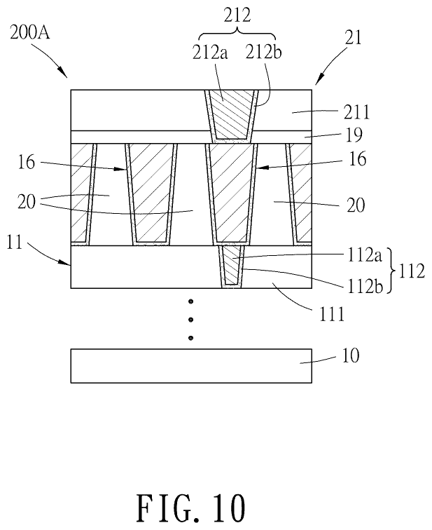

The present disclosure is directed to a semiconductor device formed with air gaps and a method for manufacturing the same. FIG. 1 is a flow diagram illustrating a method 100A for manufacturing a semiconductor device (for example, a semiconductor device 200A shown in FIG. 10) in accordance with some embodiments. FIGS. 2 to 9 illustrate schematic views of some intermediate stages of the method 100A. Some portions may be omitted in FIGS. 2 to 10 for the sake of brevity. Additional steps can be provided before, after or during the method 100A, and some of the steps described herein may be replaced by other steps or be eliminated.

Referring to FIGS. 1 and 2, the method 100A begins at step 1A, where an etch stop layer 12, a sacrificial material layer 13, and a patterned hard mask layer 14 are sequentially formed on a conductive interconnect structure 11 disposed over a substrate 10.

In some embodiments, the substrate 10 may be a semiconductor substrate, e.g., an elemental semiconductor or a compound semiconductor. An elemental semiconductor is composed of single species of atoms, such as silicon or germanium in column IV of the periodic table. A compound semiconductor is composed of two or more elements, such as silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, gallium indium arsenide phosphide, or the like. The compound semiconductor may have a gradient feature in which the composition thereof changes from one ratio at one location to another ratio at another location in the compound semiconductor. The compound semiconductor may be formed over a silicon substrate. The compound semiconductor may be strained. In some embodiments, the substrate 10 may include a multilayer compound semiconductor device. Alternatively, the substrate 10 may include a non-semiconductor material, such as a glass, fused quartz, or calcium fluoride. In some embodiments, the substrate 10 may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. In some embodiments, the substrate 10 may be doped with a p-type dopant, such as boron, aluminum, gallium, or the like, or may alternatively be doped with an n-type dopant, such as phosphorus or the like.

The conductive interconnect structure 11 is formed over the substrate 10. In some embodiments, the conductive interconnect structure 11 includes a dielectric layer 111 and an electrically conductive interconnect 112 (e.g., an electrically conductive via contact) formed in the dielectric layer 111. The dielectric layer 111 may be made of a dielectric material, for example, but not limited to, silicon oxide, SiOC-based materials (e.g., SiOCH), borophosphosilicate glass (BPSG), undoped silicate glass (USG), fluorinated silicate glass (FSG), high-density plasma (HDP) oxide, fluorine-doped silicon oxide, carbon-doped silicon oxide, porous silicon oxide, porous carbon-doped silicon oxide, organic polymers, or silicone based polymers. Other suitable dielectric materials for the dielectric layer 111 are within the contemplated scope of the present disclosure. The dielectric layer 111 may be formed over the substrate 10 by a suitable deposition process, for example, but not limited to, chemical vapor deposition (CVD), physical vapor deposition (PVD), atomic layer deposition (ALD), or other suitable deposition processes. In some embodiments, the dielectric layer 111 is formed with an opening (not shown). The electrically conductive interconnect 112 is formed in the opening of the dielectric layer 111. In some embodiments, the electrically conductive interconnect 112 includes a bulk metal portion 112a and a barrier layer 112b covering a lateral surface and a bottom surface of the bulk metal portion 112a. In some embodiments, the metal bulk portion 112a includes a low electrical resistance material, for example, but not limited to, copper (Cu), cobalt (Co), ruthenium (Ru), molybdenum (Mo), chromium (Cr), tungsten (W), rhodium (Rh), iridium (Ir), palladium (Pd), platinum (Pt), aluminum (Al), osmium (Os), niobium (Nb), rhenium (Re), vanadium (V), tantalum (Ta), or alloys thereof. Other suitable materials for the metal bulk portion 112a are within the contemplated scope of the present disclosure. In some embodiments, the barrier layer 112b includes, for example, but not limited to, a low electrical resistance material, for example, but not limited to, metal (for example, tantalum (Ta), titanium (Ti), or the like, or alloys thereof), metal nitride (tantalum nitride, titanium nitride, or the like, or combinations thereof), or combinations thereof. Other suitable materials for the barrier layer 112b are within the contemplated scope of the present disclosure. The step for forming the electrically conductive interconnect 112 may include sub-steps of: (i) conformally forming a layer of the low electrical resistance material for the barrier layer 112b on the dielectric layer 111 and in the opening; (ii) conformally forming a layer of the low electrical resistance material for the bulk metal region 112a on the layer of the low electrical resistance material for the barrier layer 112b to fill the opening; and (iii) conducting a planarization process (for example, but not limited to, CMP) to remove the low electrical resistance material for the bulk metal region 112a and the low electrical resistance material for the barrier layer 112b over the dielectric layer 111, so as to form the electrically conductive interconnect 112. In some embodiments, each of sub-steps (i) and (ii) may be conducted by a suitable deposition process, for example, but not limited to, CVD, PVD, ALD, or other suitable deposition processes. In some embodiments, the conductive interconnect structure 11 may include a plurality of the electrically conductive interconnects 112.

The etch stop layer (ESL) 12 is formed on the conductive interconnect structure 11 opposite to the substrate 10. In some embodiments, the ESL 12 may include, for example, but not limited to, metal oxide (for example, aluminum oxide, titanium oxide, tungsten oxide, or the like), metal nitride (for example, aluminum nitride, titanium nitride, tungsten nitride, or the like), metal carbide (for example, aluminum carbide, titanium carbide, tungsten carbide, or the like), a silicon-based compound (for example, silicon carbide, silicon oxycarbide, silicon carbonitride, or the like), or combinations thereof. Other suitable materials for the ESL 12 are within the contemplated scope of the present disclosure. The ESL 12 may be formed by a suitable deposition process, for example, but not limited to, CVD, PVD, ALD, PECVD, PEALD, spin-on coating, or other suitable deposition processes. In some embodiments, the deposition process may be conducted at a temperature ranging from about 50° C. to about 400° C. When the deposition process is conducted at a temperature lower than 50° C., the ESL 12 may not be formed appropriately. When the deposition process is conducted at a temperature higher than 400° C., reliability issues may occur. In some embodiments, the ESL 12 has a thickness ranging from about 10 Å to about 70 Å. When the thickness of the ESL 12 is less than 10 Å, the ESL 12 may not be an effective etch stop layer for one or more subsequent etching processes. When the thickness of the ESL 12 is larger less than 70 Å, the cost for forming the ESL 12 may be increased.

The sacrificial material layer 13 is formed on the ESL 12 opposite to the conductive interconnect structure 11. In some embodiments, the sacrificial material layer 13 may include, for example, but not limited to, metal oxide (for example, aluminum oxide, titanium oxide, tungsten oxide, or the like), metal nitride (for example, aluminum nitride, titanium nitride, tantalum nitride, or the like), metal carbide (for example, tungsten carbide, or the like), a silicon-based compound (for example, silicon, silicon oxide, or the like), or combinations thereof. Other suitable materials for the sacrificial material layer 13 are within the contemplated scope of the present disclosure. In some embodiments, the material of the sacrificial material layer 13 is different from that of the ESL 12. The sacrificial material layer 13 may be formed by a suitable deposition process, for example, but not limited to, CVD, PVD, ALD, PECVD, PEALD, spin-on coating, or other suitable deposition processes.

The patterned hard mask layer 14 is formed on the sacrificial material layer 13 opposite to the ESL 12. In some embodiments, the patterned hard mask layer 14 is obtained by forming a hard mask material layer (not shown) on the sacrificial material layer 13 and patterning the hard mask material layer. In some embodiments, the hard mask material layer includes, for example, but not limited to, silicon oxide, silicon nitride, silicon carbide, silicon oxycarbide, silicon oxynitride, silicon carbonitride, silicon oxycarbonitride, titanium, tantalum, aluminum oxide, or combinations thereof. Other suitable materials for the hard mask material layer are within the contemplated scope of the present disclosure. In some embodiments, the material of the patterned hard mask layer 14 (or the hard mask material layer) is different from that of the sacrificial material layer 13. The hard mask material layer may be formed by a suitable deposition process, for example, but not limited to, CVD, PVD, ALD, or other suitable deposition processes. In some embodiments, the hard mask material layer is patterned by etching the hard mask material layer through a patterned photoresist layer (not shown) that is used as a patterned mask. In some embodiments, the step for forming the patterned photoresist layer may include sub-step (i) forming a photoresist material layer on the hard mask material layer, and sub-step (ii) conducting a photolithography process to pattern the photoresist material layer, so as to obtain the patterned photoresist layer. In some embodiments, the photoresist material layer may be formed by a suitable deposition process, for example, but not limited to, spin-on coating or other suitable deposition processes.

Referring to FIGS. 1 and 3, the method 100A then proceeds to step 2A, where the sacrificial material layer 13 and the ESL 12 are sequentially patterned to form a plurality of trenches 15 which extend through the sacrificial material layer 13 and the ESL 12 to expose the electrically conductive interconnect 112 and portions of the dielectric layer 111 and which are spaced apart from each other. In some embodiments, the sacrificial material layer 13 and the ESL 12 are patterned through the patterned hard mask layer 14 by a suitable etching process, for example, but not limited to, an anisotropic dry etching process.

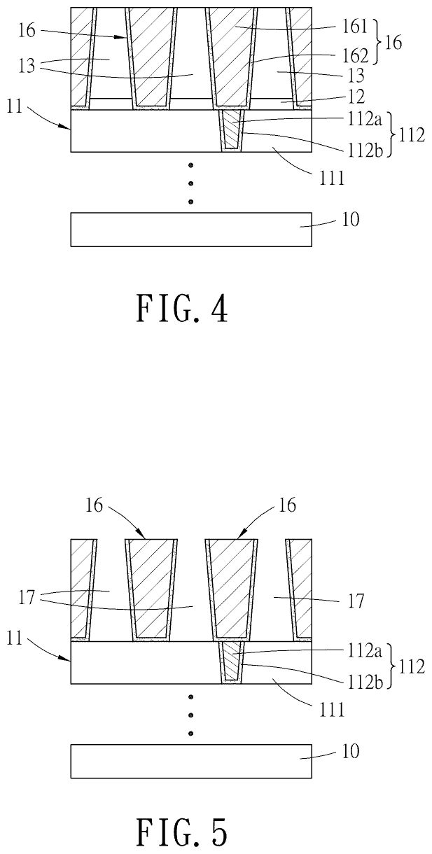

Referring to FIGS. 1 and 4, the method 100A then proceeds to step 3A, where a plurality of electrically conductive interconnects 16 (for example, metal lines) are formed in the trenches 15, respectively. The electrically conductive interconnect 112 of the conductive interconnect structure 11 is electrically connected to a corresponding one of the electrically conductive interconnects 16. In some embodiments, each of the electrically conductive interconnects 16 includes a bulk metal portion 161 and a barrier layer 162 covering a lateral surface and a bottom surface of the bulk metal portion 161. In some embodiment, the metal bulk portion includes a low electrical resistance material, for example, but not limited to, copper (Cu), cobalt (Co), ruthenium (Ru), molybdenum (Mo), chromium (Cr), tungsten (W), rhodium (Rh), iridium (Ir), palladium (Pd), platinum (Pt), aluminum (Al), osmium (Os), niobium (Nb), rhenium (Re), vanadium (V), tantalum (Ta), or alloys thereof. Other suitable materials for the bulk metal portion 161 are within the contemplated scope of the present disclosure. In some embodiments, the barrier layer 162 includes, for example, but not limited to, a low electrical resistance material, for example, but not limited to, metal (for example, tantalum (Ta), titanium (Ti), or the like, or alloys thereof), metal nitride (tantalum nitride, titanium nitride, or the like, or combinations thereof), or combinations thereof. Other suitable materials for the barrier layer 162 are within the contemplated scope of the present disclosure. The step for forming the electrically conductive interconnects 16 may include sub-steps of: (i) conformally forming a layer of the low electrical resistance material for the barrier layer 162 on the structure shown in FIG. 3 and in the trenches 15; (ii) conformally forming a layer of the low electrical resistance material for the bulk metal region 161 on the layer of the low electrical resistance material for the barrier layer 162 to fill the trenches 15; and (iii) conducting a planarization process (for example, but not limited to, CMP) to remove the low electrical resistance material for the bulk metal region 161 and the low electrical resistance material for the barrier layer 162 over the sacrificial material layer 13 and also to remove the patterned hard mask layer 14, so as to form the electrically conductive interconnects 16. In some embodiments, each of sub-steps (i) and (ii) may be conducted by a suitable deposition process, for example, but not limited to, CVD, PVD, ALD, or other suitable deposition processes.

Referring to FIGS. 1 and 5, the method 100A then proceeds to step 4A, where the sacrificial material layer 13 is removed. The sacrificial material layer 13 of the structure shown in FIG. 4 is removed to form a plurality of trenches 17. Two adjacent ones of the electrically conductive interconnects 16 are spaced apart from each other by a corresponding one of the trenches 17. Portions of the dielectric layer 111 of the conductive interconnect structure 11 are exposed through the trenches 17. In some embodiments, the sacrificial material layer 13 is removed by a suitable selective etching process, for example, but not limited to, a wet etching process, a dry etching process, or a combination thereof. In some embodiments in which the sacrificial material layer 13 includes the metal oxide (for example, aluminum oxide, titanium oxide, tungsten oxide, or the like), the sacrificial material layer 13 may be removed by an etching process using diluted hydrofluoric acid as an etchant.

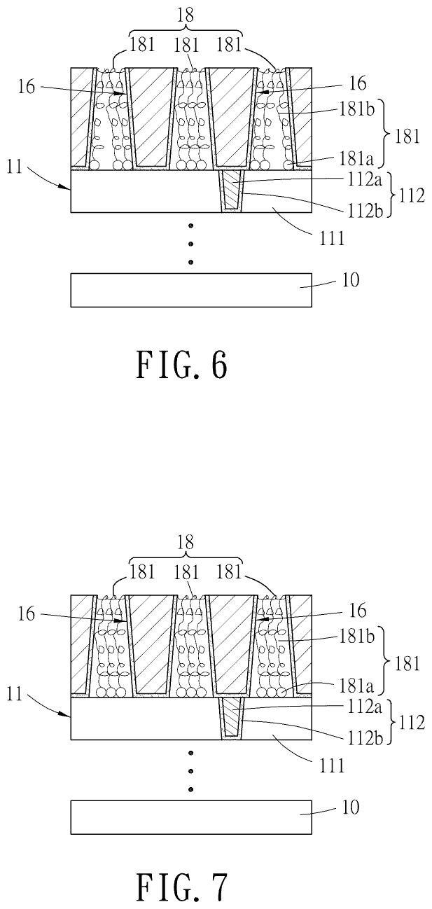

Referring to FIGS. 1 and 6, the method 100A then proceeds to step 5A, where a self-assembled monolayer (SAM) 18 is formed to fill the trenches 17 of the structure shown in FIG. 5. The SAM 18 includes a plurality of functionalized molecules 181. Each of the functionalized molecules 181 includes a head group 181a bonded to an upper surface of the dielectric layer 111 exposed through the trenches 17, and a carbon-based tail group 181b bonded to the head group 181a. In some embodiments, the head group 181a includes a siloxy radical or a carboxyl radical serving as a bonding radical which is bonded to the upper surface of the dielectric layer 111 exposed through the trenches 17. The SAM 18 has an upper end distal from the upper surface of the dielectric layer 111, each of the electrically conductive interconnects 16 has an upper end distal from the upper surface of the dielectric layer 111, and the upper end of the SAM 18 is flush with the upper end of each of the electrically conductive interconnects 16. In some embodiments, The SAM 18 has a thickness that is the same as a height of the electrically conductive interconnects 16. In some embodiments, the thickness of the SAM 18 ranges from about 100 Å to about 400 Å. A molecular weight of the carbon-based tail group 181b of each of the functionalized molecules 181 is controlled so as to permit the upper end of the SAM 18 to be flush with the upper end of each of the electrically conductive interconnects 16. In some embodiments, the molecular weight of the carbon-based tail group 181b of each of the functionalized molecules 181 ranges from about 15 to about 2000. In some embodiments, the SAM 18 is formed by a suitable deposition process, for example, but not limited to, CVD, ALD, spin-on coating, or other suitable deposition processes. In some embodiments, the deposition process is conducted at a temperature ranging from about 10° C. to about 300° C. When the deposition process is conducted by spin-on coating at a temperature lower than 10° C., a solution of a precursor for forming the SAM 18 may coagulate, and thus the SAM 18 cannot be formed. When the deposition process is conducted by CVD or ALD at a temperature lower than 10° C., a reaction rate for forming the SAM 18 is lowered. When the deposition process is conducted at a temperature higher than 300° C., the SAM 18 may be damaged or burned out.

In some embodiments, the precursor for forming the functionalized molecules 181 of the SAM 18 includes, for example, but not limited to, a silane-based compound, an aminosilane-based compound, a carboxylic acid-based compound, or combinations thereof.

In some embodiments, the silane-based compound has formula (I)

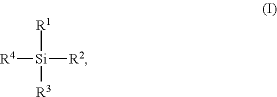

wherein
each of R¹, R², and R³ is independently an aliphatic hydrocarbyl group of C₁ to C₆ or an aliphatic hydrocarbyloxy group of C₁ to C₆ with proviso that at least one of R¹, R², and R³ is the aliphatic hydrocarbyloxy group of C₁ to C₆, and
R⁴ is a hydrocarbyl group of C₁ to C₁₀₀ or a mercaptohydrocarbyl group of C₁ to C₁₀₀. In some embodiments, each of R¹, R², and R³ is independently an alkyl group of C₁ to C₆ or an alkoxy group of C₁ to C₆ with proviso that at least one of R¹, R², and R³ is the alkoxy group of C₁ to C₆, and R⁴ is an alkyl group of C₁ to C₁₀₀ or a mercaptoalkyl group of C₁ to C₁₀₀.

In some embodiments, the silane-based compound includes, for example, but not limited to, trimethyl methoxysilane, triethyl methoxysilane, tripropyl methoxysilane, tributyl methoxysilane, tripentyl methoxysilane, trihexyl methoxysilane, triheptyl methoxysilane, trioctyl methoxysilane, trinonyl methoxysilane, tridecyl methoxysilane, methyltrimethoxysilane, ethyltrimethoxysilane, propyltrimethoxysilane, butyltrimethoxysilane, pentyltrimethoxysilane, hexyltrimethoxysilane, heptyltrimethoxysilane, octyltrimethoxysilane, nonyltrimethoxysilane, decyltrimethoxysilane, mercaptomethyltrimethoxy silane, mercaptoethyltrimethoxy silane, mercaptopropyltrimethoxy silane, mercaptobutyltrimethoxy silane, mercaptopentyltrimethoxy silane, mercaptohexyltrimethoxy silane, mercaptoheptyltrimethoxy silane, mercaptooctyltrimethoxy silane, mercaptononyltrimethoxy silane, mercaptodecyltrimethoxy silane, and the like.

In some embodiments, the aminosilane-based compound has formulae (II), (III), or (IV)

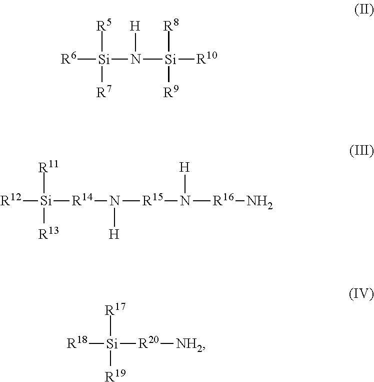

wherein
each of R⁵, R⁶, R⁷, R⁸, R⁹, and R¹⁰ is independently a hydrocarbyl group of C₁ to C₁₀₀ or a mercaptohydrocarbyl group of C₁ to C₁₀₀,
each of R¹¹, R¹², and R¹³ is independently an aliphatic hydrocarbyl group of C₁ to C₆ or an aliphatic hydrocarbyloxy group of C₁ to C₆ with proviso that at least one of R¹¹, R¹², and R¹³ is the aliphatic hydrocarbyloxy group of C₁ to C₆,
each of R¹⁴, R¹⁵, and R¹⁶ is independently a hydrocarbylene group of C₁ to C₁₀₀,
each of R¹⁷, R¹⁸, and R¹⁹ is independently an aliphatic hydrocarbyl group of C₁ to C₆ or an aliphatic hydrocarbyloxy group of C₁ to C₆ with proviso that at least one of R¹⁷, R¹⁸, and R¹⁹ is the aliphatic hydrocarbyloxy group of C₁ to C₆, and
R²⁰ is a hydrocarbylene group of C₁ to C₁₀₀. In some embodiments, each of R⁵, R⁶, R⁷, R⁸, R⁹, and R¹⁰ is independently an alkyl group of C₁ to C₁₀₀ or a mercaptoalkyl group of C₁ to C₁₀₀. Each of R¹¹, R¹², and R¹³ is independently an alkyl group of C₁ to C₆ or an alkoxy group of C₁ to C₆ with proviso that at least one of R¹¹, R¹², and R¹³ is the alkoxy group of C₁ to C₆. Each of R¹⁴, R¹⁵, and R¹⁶ is independently an alkylene group of C₁ to C₁₀₀. Each of R¹⁷, R¹⁸, and R¹⁹ is independently an alkyl group of C₁ to C₆ or an alkoxy group of C₁ to C₆ with proviso that at least one of R¹⁷, R¹⁸, and R¹⁹ is the alkoxy group of C₁ to C₆. R²⁰ is an alkylene group of C₁ to C₁₀₀.

In some embodiments, the aminosilane-based compound includes hexamethyldisilazane, hexaethyldisilazane, hexapropyldisilazane, hexabutyldisilazane, hexapentyldisilazane, hexahexyldisilazane, hexaheptyldisilazane, hexaoctyldisilazane, hexanonyldisilazane, hexadecyldisilazane, 3-trimethoxysilyl propyl diethylene triamine, 3-triethoxysilyl propyl diethylene triamine, 3-tripropoxysilyl propyl diethylene triamine, 3-trimethoxysilyl methyl diethylene triamine, 3-trimethoxysilyl ethyl diethylene triamine, 3-trimethoxysilyl butyl diethylene triamine, 3-trimethoxysilyl penyl diethylene triamine, 3-aminopropyl trimethoxy silane, 3-aminopropyl triethoxy silane, 3-aminopropyl tripropoxy silane, and the like.

In some embodiments, the carboxylic acid-based compound has formula (V)

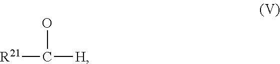

wherein R²¹ is a hydrocarbyl group of C₁ to C₁₀₀ or a mercaptohydrocarbyl group of C₁ to C₁₀₀. In some embodiment, R²¹ is an alkyl group of C₁ to C₁₀₀ or a mercaptoalkyl group of C₁ to C₁₀₀.

In some embodiments, the carboxylic acid-based compound includes, for example, but not limited to, hexanoic acid, heptanoic acid, octanoic acid, nonanoic acid, decanoic acid, undecanoic acid, dodecanoic acid, tridecanoic acid, tetradecanoic acid, pentadecanoic acid, hexadecanoic acid, and the like.

Referring to FIGS. 1 and 7, the method 100A then proceeds to step 6A, where the SAM 18 is subjected to a rearrangement treatment. As shown in FIG. 6, due to defects (for example, but not limited, the precursor and/or other impurities) remaining on the upper surface of the dielectric layer 111, the functionalized molecules 181 of the SAM 18 may be unevenly bonded to the upper surface of the dielectric layer 111. Therefore, the functionalized molecules 181 of the SAM 18 are subjected to the rearrangement treatment so as to remove the precursor and/or the impurities and to permit the functionalized molecules 181 to be rearranged and to be evenly bonded on the upper surface of the dielectric layer 111. In some embodiments, the rearrangement treatment is conducted by an annealing process at a temperature ranging from about 100° C. to about 250° C. When the annealing process is conducted at a temperature lower than 100° C., the functionalized molecules 181 cannot be rearranged appropriately. When the annealing process is conducted at a temperature higher than 250° C., the functionalized molecules 181 may be burned out and/or the reliability issues may occur.

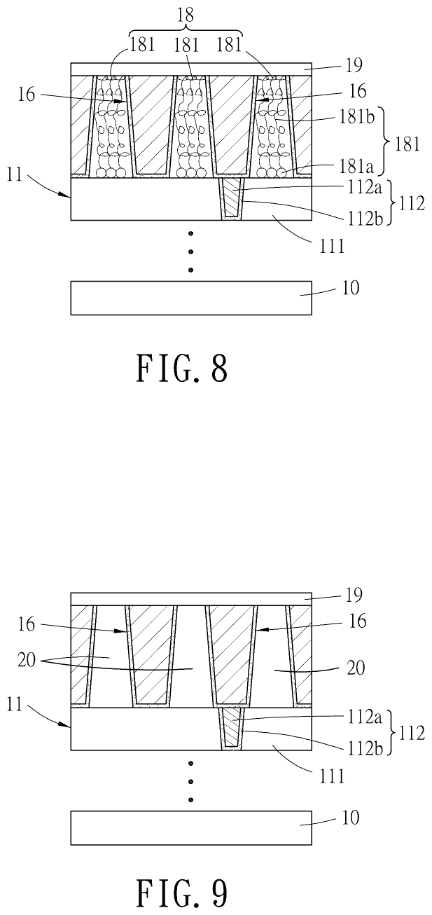

Referring to FIGS. 1 and 8, the method 100A then proceeds to step 7A, where an etch stop layer (ESL) 19 is formed. The ESL 19 is formed on the electrically conductive interconnects 16 and the SAM 18 opposite to the conductive interconnect structure 11. The material and process for forming the ESL 19 may be the same as or similar to those for forming the ESL 12 as described in step 1A, and thus details thereof are omitted for the sake of brevity.

Referring to FIGS. 1 and 9, the method 100A then proceeds to step 8A, where a plurality of air gaps 20 are formed. The SAM 18 of the structure shown in FIG. 8 is removed to form the air gaps 20. In some embodiments, the SAM 18 is removing by burning out at a temperature ranging from about 250° C. to about 350° C. to vaporize the SAM 18 through the ESL 19. When the temperature for burning out the SAM 18 is lower than 250° C., the SAM 18 may not be removed completely. When the temperature for burning out the SAM 18 is higher than 350° C., the reliability issues may occur. In order to permit the SAM 18 to be removed efficiently through the ESL 19, the ESL 19 has a porosity ranging from about 2% to about 5%. When the porosity of the ESL 19 is lower than 2%, the SAM 18 cannot not be efficiently removed through the ESL 19. When the porosity of the ESL 19 is higher than 5%, the ESL 19 may be damaged during burning-out of the SAM 18 due to a low mechanical strength thereof. Two adjacent ones of the electrically conductive interconnects 16 are spaced apart from each other by a corresponding one of the air gap 20. As described above and shown in FIG. 8, the upper end of the SAM 18 is flush with the upper end of each of the electrically conductive interconnects 16. Therefore, an upper end of each of the air gaps 20 formed by removing the SAM 18 is flush with the upper end of each of the electrically conductive interconnects 16. In some embodiments, the air gaps 20 have a height which is the same as the height of the electrically conductive interconnects 16.

Referring to FIGS. 1 and 10, the method 100A then proceeds to step 9A, where a conductive interconnect structure 21 is formed, thereby obtaining the semiconductor device 200A accordingly. The conductive interconnect structure 21 includes a dielectric layer 211 and an electrically conductive interconnect 212 (e.g., an electrically conductive via contact). The dielectric layer 211 of the conductive interconnect structure 21 is formed on the ESL 19. The material and process for forming the dielectric layer 211 of the conductive interconnect structure 21 are similar to those of the dielectric layer 111 as described in step 1A, and thus details thereof are omitted for the sake of brevity. The electrically conductive interconnect 212 of the conductive interconnect structure 21 penetrates the dielectric layer 211 and the ESL 19, and is disposed on and electrically connected to a corresponding one of the electrically conductive interconnects 16. In some embodiments, the electrically conductive interconnect 212 includes a bulk metal portion 212a and a barrier layer 212b which covers a lateral surface and a bottom surface of the bulk metal portion 212a. The materials and processes for forming the electrically conductive interconnect 212 are similar to those of the electrically conductive interconnect 112 as described in step 1A, and thus details thereof are omitted for the sake of brevity.

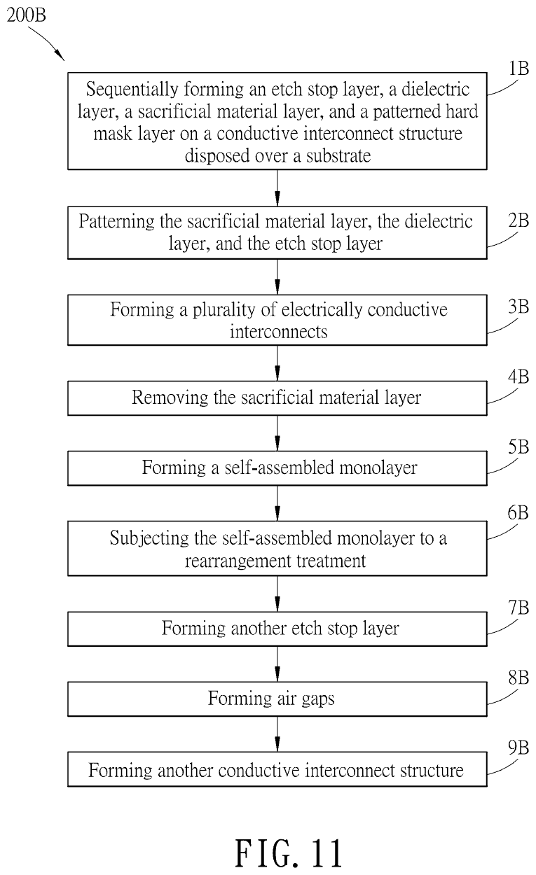

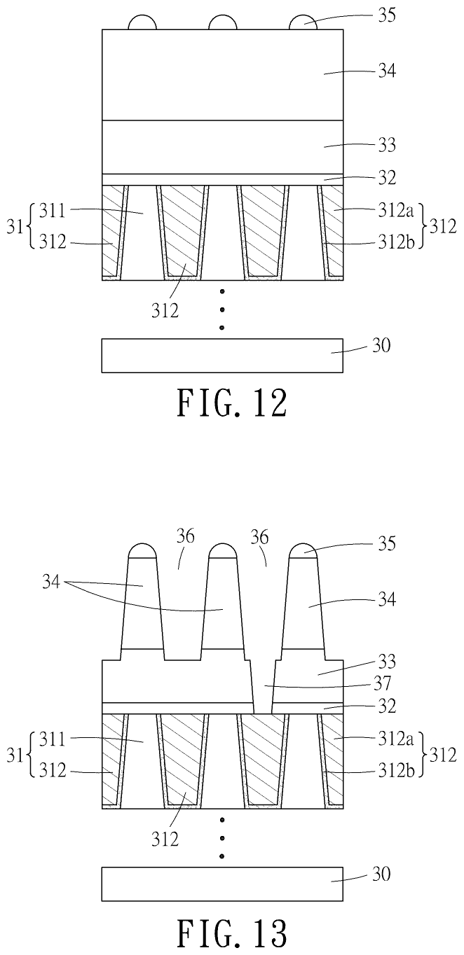

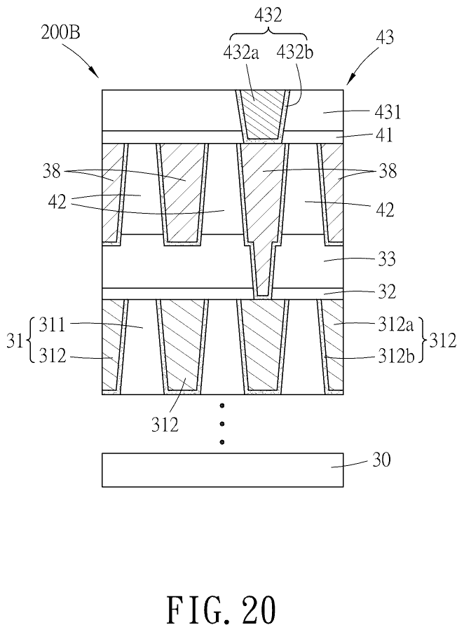

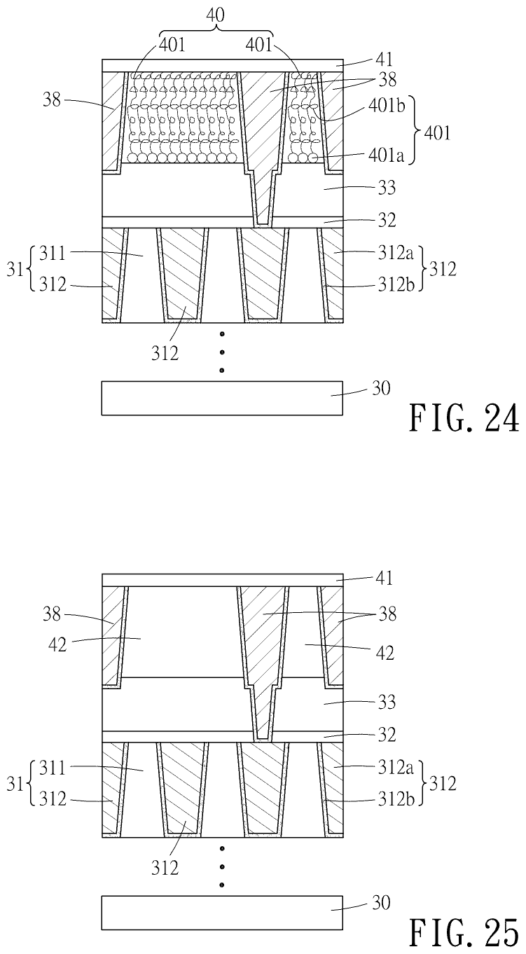

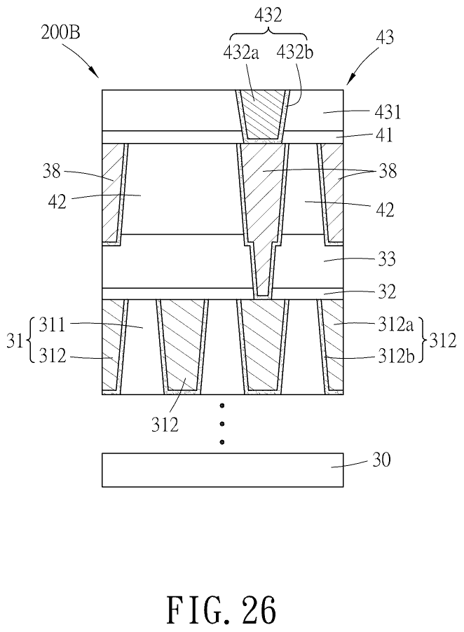

FIG. 11 is a flow diagram illustrating a method 100B for manufacturing a semiconductor device (for example, a semiconductor device 200B shown in FIGS. 20 and 26) in accordance with some embodiments. FIGS. 12 to 26 illustrate schematic views of some intermediate stages of the method 100B. Some portions may be omitted in FIGS. 12 to 26 for the sake of brevity. Additional steps can be provided before, after or during the method 100B, and some of the steps described herein may be replaced by other steps or be eliminated.

Referring to FIGS. 11 and 12, the method 100B begins at step 1B, where an etch stop layer 32, a dielectric layer 33, a sacrificial material layer 34, and a patterned hard mask layer 35 are sequentially formed on a conductive interconnect structure 31 disposed over a substrate 30.

In some embodiments, the material for the substrate 30 may be the same as or similar to that for the substrate 10 as described in step 1A, and thus details thereof are omitted for the sake of brevity.

The conductive interconnect structure 31 is formed over the substrate 30. In some embodiments, the conductive interconnect structure 31 includes a dielectric layer 311 and a plurality of electrically conductive interconnects 312 (e.g., metal lines) formed in the dielectric layer 311. The material and process for forming the dielectric layer 311 may be the same as or similar to those for forming the dielectric layer 111 as described in step 1A, and thus details thereof are omitted for the sake of brevity. In some embodiments, each of the electrically conductive interconnects 312 includes a bulk metal portion 312a and a barrier layer 312b covering a lateral surface and a bottom surface of the bulk metal portion 312a. The materials and processes for forming the electrically conductive interconnects 312 may be the same as or similar to those for forming the electrically conductive interconnects 16 as described in step 3A, and thus details thereof are omitted for the sake of brevity.

The etch stop layer (ESL) 32 is formed on the conductive interconnect structure 31 opposite to the substrate 30. In some embodiments, the material and process for forming the ESL 32 may be the same as or similar to those for forming the ESL 12 as described in step 1A, and thus details thereof are omitted for the sake of brevity.

The dielectric layer 33 is formed on the ESL 32 opposite to the conductive interconnect structure 31. In some embodiments, the material and process for forming the dielectric layer 33 may be the same as or similar to those for forming the dielectric layer 111 as described in step 1A, and thus details thereof are omitted for the sake of brevity.

The sacrificial material layer 34 is formed on the dielectric layer 33 opposite to the ESL 32. In some embodiments, the material and process for forming the sacrificial material layer 34 may be the same as or similar to those for forming the sacrificial material layer 13 as described in step 1A, and thus details thereof are omitted for the sake of brevity.

The patterned hard mask layer 35 is formed on the sacrificial material layer 34 opposite to the dielectric layer 33. In some embodiments, the material and process for forming the patterned hard mask layer 35 may be the same as or similar to those for forming the patterned hard mask layer 14 as described in step 1A, and thus details thereof are omitted for the sake of brevity.

Referring to FIGS. 11 and 13, the method 100B then proceeds to step 2B, where the sacrificial material layer 34, the dielectric layer 33, and the ESL 32 are sequentially patterned to form a plurality of trenches 36 separated from each other and a via opening 37. In some embodiments, the sacrificial material layer 34, the dielectric layer 33, and the ESL 32 are patterned through the patterned hard mask layer 35 by a suitable etching process, for example, but not limited to, an anisotropic dry etching process. Since the sacrificial material layer 34 is directly formed on the dielectric layer 33 without formation of an etch stop layer therebetween, the trenches 36 extend through the sacrificial material layer 34 and further into an upper portion of the dielectric layer 33. The via opening 37 is formed below and in spatial communication with a corresponding one of the trenches 36, so as to expose a corresponding one of the electrically conductive interconnects 312 through the via opening 37 and the corresponding one of the trenches 36. In some embodiments, a plurality of the via openings 37 may be formed, and each of the via openings 37 is formed below and in spatial communication with a corresponding one of the trenches 36, so as to expose a corresponding one of the electrically conductive interconnects 312 through the each of the via openings 37 and the corresponding one of the trenches 36.

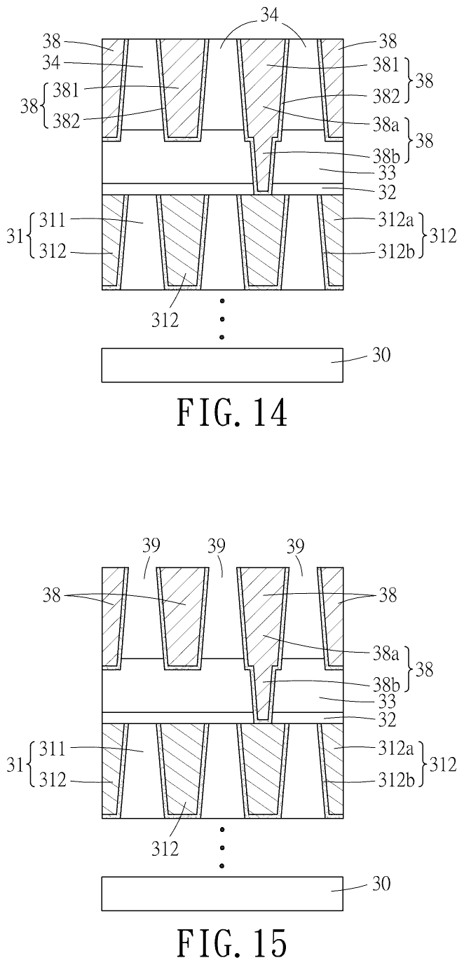

Referring to FIGS. 11 and 14, the method 100B then proceeds to step 3B, where a plurality of electrically conductive interconnects 38 are formed in the trenches 36 and the via opening 37. The electrically conductive interconnects 38 protrude upwardly from an upper surface of the dielectric layer 33. In some embodiments, each of the electrically conductive interconnects 38 includes a bulk metal portion 381 and a barrier layer 382 covering a lateral surface and a bottom surface of the bulk metal portion 1381. In some embodiments, one of the electrically conductive interconnects 38 includes an upper interconnect portion 38a and a lower interconnect portion 38b disposed below the upper interconnect portion 38a. The upper interconnect portion 38a of the one of the electrically conductive interconnects 38 and the other ones of the electrically conductive interconnects 38 serve as metal lines, respectively. The lower interconnect portion 38b of the one of the electrically conductive interconnects 38 serves as an electrically conductive via contact, and is disposed between and electrically connected to the upper interconnect portion 38a of the one of the electrically conductive interconnects 38 and a corresponding one of the electrically conductive interconnects 312. In some embodiments, each of two or more of the electrically conductive interconnects 38 may include the upper interconnect portion 38a and the lower interconnect portion 38b. The materials and processes for forming the electrically conductive interconnects 38 may be the same as or similar to those for forming the electrically conductive interconnects 16 as described in step 3A, and thus details thereof are omitted for the sake of brevity.

Referring to FIGS. 11 and 15, the method 100B then proceeds to step 4B, where the sacrificial material layer 34 is removed. The sacrificial material layer 34 of the structure shown in FIG. 14 is removed to form a plurality of trenches 39. Two adjacent ones of the electrically conductive interconnects 38 are spaced apart from each other by a corresponding one of the trenches 39. Portions of the dielectric layer 33 are exposed through the trenches 39. The process for removing the sacrificial material layer 34 may be the same as or similar to that for removing the sacrificial material layer 13 as described in step 4A, and thus details thereof are omitted for the sake of brevity.

Referring to FIGS. 11 and 16, the method 100B then proceeds to step 5B, where a self-assembled monolayer (SAM) 40 is formed to fill the trenches 39 of the structure shown in FIG. 15. The SAM 40 includes a plurality of functionalized molecules 401. Each of the functionalized molecules 401 includes a head group 401a bonded to an upper surface of the dielectric layer 33 exposed through the trenches 39, and a carbon-based tail group 401b bonded to the head group 401a. The material and process for forming the SAM 40 may be the same as or similar to those for forming the SAM 18 as described in step 5A and the properties of the functionalized molecules 401 may be the same or similar to those of the functionalized molecules 181 as described in step 5A, and thus details thereof are omitted for the sake of brevity.

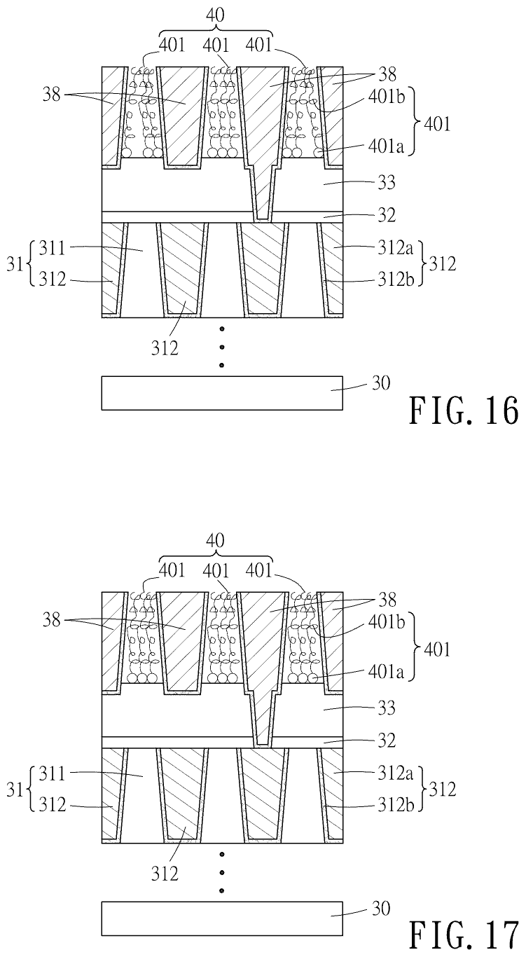

Referring to FIGS. 11 and 17, the method 100B then proceeds to step 6B, where the SAM 40 is subjected to a rearrangement treatment. The process for the rearrangement treatment of the functionalized molecules 401 of the SAM 40 may be the same as or similar to that for the rearrangement treatment of the functionalized molecules 181 of the SAM 18 as described in step 6A, and thus details thereof are omitted for the sake of brevity.

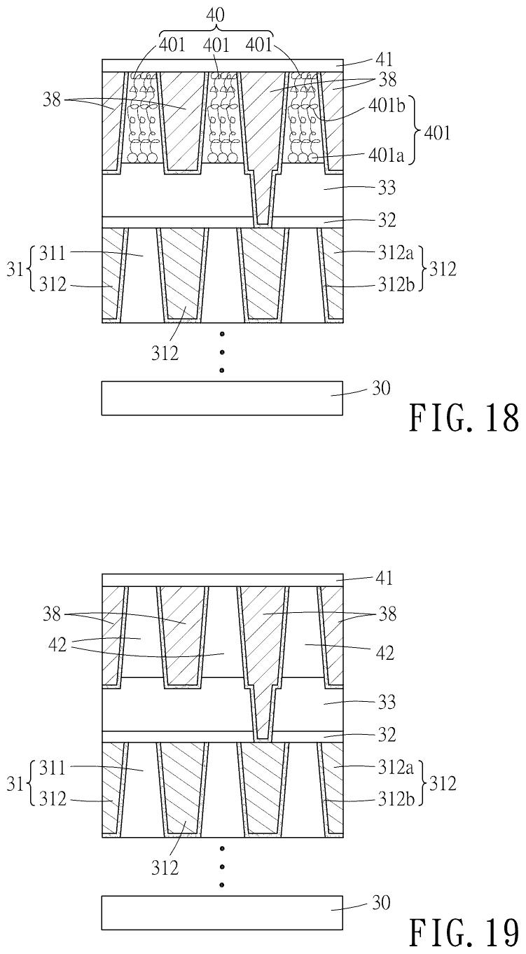

Referring to FIGS. 11 and 18, the method 100B then proceeds to step 7B, where an etch stop layer (ESL) 41 is formed. The ESL 41 is formed on the electrically conductive interconnects 38 and the SAM 40 opposite to the dielectric layer 33. The material and process for forming the ESL 41 may be the same as or similar to those for forming the ESL 12 as described in step 1A, and thus details thereof are omitted for the sake of brevity.

Referring to FIGS. 11 and 19, the method 100B then proceeds to step 8B, where a plurality of air gaps 42 are formed. The SAM 40 of the structure shown in FIG. 18 is removed to form the air gaps 42. The process for removing the SAM 40 may be the same as or similar to that for removing the SAM 18 as described in step 8A, and thus details thereof are omitted for the sake of brevity. Two adjacent ones of the electrically conductive interconnects 38 are spaced apart from each other by a corresponding one of the air gap 42. As described above and shown in FIG. 18, the upper end of the SAM 40 is flush the upper end of each of the electrically conductive interconnects 38. Therefore, an upper end of each of the air gaps 42 formed by removing the SAM 40 is flush with the upper end of each of the electrically conductive interconnects 38.

Referring to FIGS. 11 and 20, the method 100B then proceeds to step 9B, where a conductive interconnect structure 43 is formed, thereby obtaining the semiconductor device 200B accordingly. The conductive interconnect structure 43 includes a dielectric layer 431 and an electrically conductive interconnect 432 (e.g., an electrically conductive via contact). The dielectric layer 431 of the conductive interconnect structure 43 is formed on the ESL 41. The material and process for forming the dielectric layer 431 of the conductive interconnect structure 43 are similar to those of the dielectric layer 111 as described in step 1A, and thus details thereof are omitted for the sake of brevity. The electrically conductive interconnect 432 of the conductive interconnect structure 43 penetrates the dielectric layer 431 and the ESL 41, and is disposed on and electrically connected to a corresponding one of the electrically conductive interconnects 38. In some embodiments, the electrically conductive interconnect 432 includes a bulk metal portion 432a and a barrier layer 432b which covers a lateral surface and a bottom surface of the bulk metal portion 432a. The materials and processes for forming the electrically conductive interconnect 432 are similar to those of the electrically conductive interconnect 112 as described in step 1A, and thus details thereof are omitted for the sake of brevity.

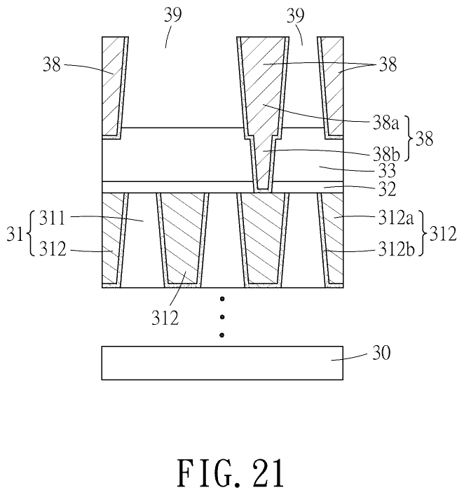

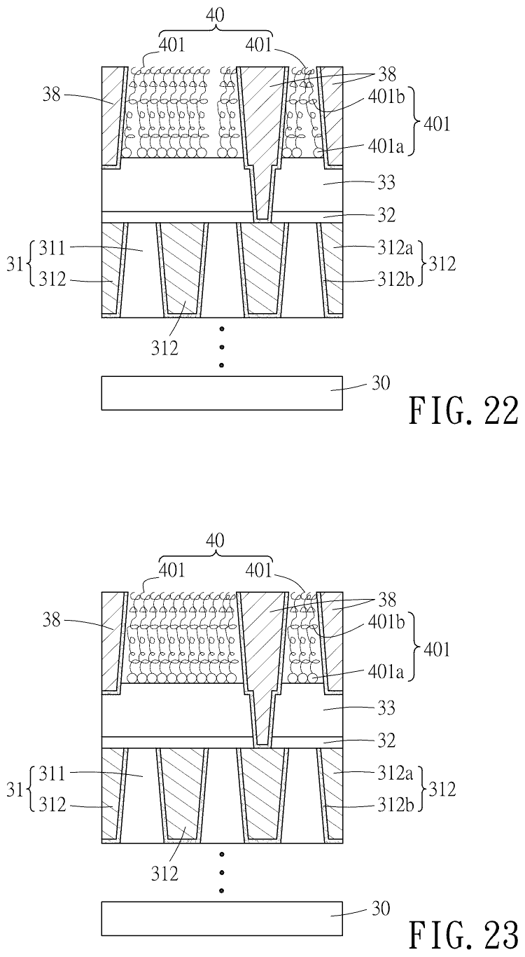

Referring to FIGS. 21 to 26, which show the structures similar to those shown in FIGS. 15 to 20, respectively, in some other embodiments, the trenches 39 formed after step 4B of the method 100B may have different widths (see FIG. 21). In step 5B (i.e., formation of the SAM 40) of the method 100B, the upper end of the SAM 40 thus formed (see FIG. 22) may also be flush with the upper end of each of the electrically conductive interconnects 38 by controlling the molecular weight of the carbon-based tail group 401b of each of the functionalized molecules 401. Therefore, in step 8B (i.e., formation of the air gaps 42) of the method 100B, the upper end of each of the air gaps 42 having different widths is also flush with the upper end of each of the electrically conductive interconnects 38.

Similarly, referring to FIG. 5, in some other embodiments, the trenches 17 formed after step 4A of the method 100A may have different widths (not shown). In step 5A (i.e., formation of the SAM 18) of the method 100A, the upper end of the SAM 18 thus formed may also be flush with the upper end of each of the electrically conductive interconnects 16 by controlling the molecular weight of the carbon-based tail group 181b of each of the functionalized molecules 181. Therefore, in step 8A (i.e., formation of the air gaps 20) of the method 100A, the upper end of each of the air gaps 20 having different widths (now shown) is also flush with the upper end of each of the electrically conductive interconnects 16.

In the method of present disclosure, by selectively bonding functionalized molecules to an upper surface of a dielectric layer exposed through trenches formed among electrically conductive interconnects (e.g., metal lines) to form a self-assembled monolayer filled in the trenches, and by burning out the self-assembled monolayer after forming an etch stop layer on the self-assembled monolayer and the electrically conductive interconnects, a plurality of air gaps are formed among the electrically conductive interconnects. The molecular weight of the functionalized molecules can be controlled to permit an upper end of the self-assembled monolayer to be flush with an upper end of each of the electrically conductive interconnects. Therefore, an upper end of each of the air gaps is flush with an upper end of each of the electrically conductive interconnects, which is conducive to reducing a resistance-capacitance (RC) delay and electronic interference in a semiconductor device. In addition, a height of each of the air gaps is controlled by the molecular weight of the functionalized molecules of the self-assembled monolayer. Therefore, an air gap loading in formation of the air gaps having different widths can be reduced. Moreover, an etching-back process is not required in formation of the air gaps, and hence risk of damage to the electrically conductive interconnects can be reduced, thereby preventing increased resistance of the semiconductor device.

In accordance with some embodiments of the present disclosure, a method for manufacturing a semiconductor device includes: forming a plurality of first conductive interconnects which are spaced apart from each other and which protrude upwardly from an upper surface of a dielectric layer that is disposed over a substrate, so as to form a plurality of trenches among the plurality of the first conductive interconnects; forming a plurality of functionalized molecules such that the plurality of functionalized molecules are bonded to the upper surface of the dielectric layer so as to form a self-assembled monolayer filled in the plurality of the trenches; subjecting the plurality of the functionalized molecules to a rearrangement treatment so as to permit the plurality of the functionalized molecules to be evenly bonded on the upper surface of the dielectric layer; forming an etch stop layer on the plurality of the first conductive interconnects and the self-assembled monolayer; and removing the self-assembled monolayer to form a plurality of air gaps so that two adjacent ones of the plurality of the first conductive interconnects are spaced apart from each other by a corresponding one of the plurality of the air gaps.

In accordance with some embodiments of the present disclosure, the self-assembled monolayer has an upper end distal from the upper surface of the dielectric layer, each of the plurality of the first conductive interconnects has an upper end distal from the upper surface of the dielectric layer, and the upper end of the self-assembled monolayer is flush with the upper end of each of the plurality of the first conductive interconnects.

In accordance with some embodiments of the present disclosure, each of the plurality of the functionalized molecules includes a head group bonded to the upper surface of the dielectric layer and a carbon-based tail group bonded to the head group. The carbon-based tail group has a molecular weight ranging from about 15 to about 2000.

In accordance with some embodiments of the present disclosure, the head group includes a siloxy radical or a carboxyl radical bonded to the upper surface of the dielectric layer.

In accordance with some embodiments of the present disclosure, each of the plurality of the air gaps has an upper end distal from the upper surface of the dielectric layer, and the upper end of each of the plurality of the air gaps is flush with the upper end of each of the plurality of the first conductive interconnects.

In accordance with some embodiments of the present disclosure, the plurality of the functionalized molecules are formed using a precursor which includes a silane-based compound, an aminosilane-based compound, a carboxylic acid-based compound, or combinations thereof.

In accordance with some embodiments of the present disclosure, the silane-based compound has formula (I)

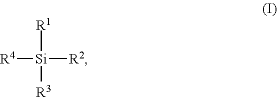

wherein
each of R¹, R², and R³ is independently an aliphatic hydrocarbyl group of C₁ to C₆ or an aliphatic hydrocarbyloxy group of C₁ to C₆ with proviso that at least one of R¹, R², and R³ is the aliphatic hydrocarbyloxy group of C₁ to C₆, and
R⁴ is a hydrocarbyl group of C₁ to C₁₀₀ or a mercaptohydrocarbyl group of C₁ to C₁₀₀.

In accordance with some embodiments of the present disclosure, the amino silane-based compound has formulae (II), (III), or (IV)

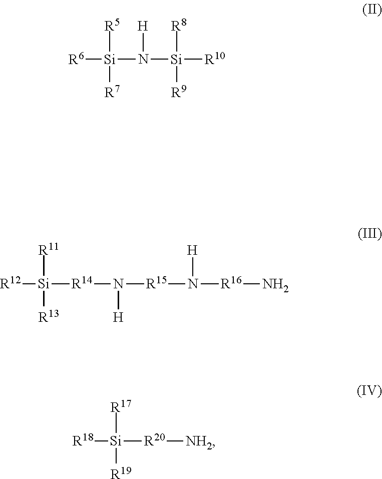

wherein
each of R⁵, R⁶, R⁷, R⁸, R⁹, and R¹⁰ is independently a hydrocarbyl group of C₁ to C₁₀₀ or a mercaptohydrocarbyl group of C₁ to C₁₀₀,
each of R¹¹, R¹², and R¹³ is independently an aliphatic hydrocarbyl group of C₁ to C₆ or an aliphatic hydrocarbyloxy group of C₁ to C₆ with proviso that at least one of R¹¹, R¹², and R¹³ is the aliphatic hydrocarbyloxy group of C₁ to C₆,
each of R¹⁴, R¹⁵, and R¹⁶ is independently a hydrocarbylene group of C₁ to C₁₀₀,
each of R¹⁷, R¹⁸, and R¹⁹ is independently an aliphatic hydrocarbyl group of C₁ to C₆ or an aliphatic hydrocarbyloxy group of C₁ to C₆ with proviso that at least one of R¹⁷, R¹⁸, and R¹⁹ is the aliphatic hydrocarbyloxy group of C₁ to C₆, and
R²⁰ is a hydrocarbylene group of C₁ to C₁₀₀.

In accordance with some embodiments of the present disclosure, the carboxylic acid-based compound has formula (V)

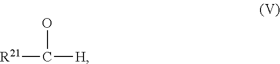

wherein R²¹ is a hydrocarbyl group of C₁ to C₁₀₀ or a mercaptohydrocarbyl group of C₁ to C₁₀₀.

In accordance with some embodiments of the present disclosure, the rearrangement treatment is conducted by an annealing process at a temperature ranging from about 100° C. to about 250° C.

In accordance with some embodiments of the present disclosure, the self-assembled monolayer is removed by burning out the plurality of the functionalized molecules at a temperature ranging from about 250° C. to about 350° C.

In accordance with some embodiments of the present disclosure, the etch stop layer has a porosity ranging from about 2% to about 5%.

In accordance with some embodiments of the present disclosure, the method for manufacturing a semiconductor device further includes: forming a conductive interconnect structure over the substrate. The conductive interconnect structure includes the dielectric layer and a second conductive interconnect which is disposed in the dielectric layer and which is electrically connected to a corresponding one of the plurality of first conductive interconnects.

In accordance with some embodiments of the present disclosure, the method for manufacturing a semiconductor device further includes: forming a conductive interconnect structure between the dielectric layer and the substrate. The conductive interconnect structure includes a plurality of second conductive interconnects spaced apart from each other. One of the plurality of the first conductive interconnects penetrates the dielectric layer and is electrically connected to a corresponding one of the plurality of the second conductive interconnects.

In accordance with some embodiments of the present disclosure, a method for manufacturing a semiconductor device includes: forming a conductive interconnect structure over a substrate, the conductive interconnect structure including a dielectric layer and a first conductive interconnect disposed in the dielectric layer; forming a plurality of second conductive interconnects on the conductive interconnect structure, the plurality of the second conductive interconnects being spaced apart from each other so as to form a plurality of trenches among the plurality of the second conductive interconnects, the first conductive interconnect being electrically connected to a corresponding one of the plurality of the second conductive interconnects; forming a plurality of functionalized molecules such that the plurality of functionalized molecules are bonded to an upper surface of the dielectric layer so as to form a self-assembled monolayer filled in the plurality of the trenches; subjecting the plurality of the functionalized molecules to a rearrangement treatment so as to permit the plurality of the functionalized molecules to be evenly bonded on the upper surface of the dielectric layer; forming an etch stop layer on the plurality of the second conductive interconnects and the self-assembled monolayer; and removing the self-assembled monolayer to form a plurality of air gaps so that two adjacent ones of the plurality of the second conductive interconnects are spaced apart from each other by a corresponding one of the plurality of the air gaps.

In accordance with some embodiments of the present disclosure, the plurality of the functionalized molecules are formed using a silane-based compound having formula (I)

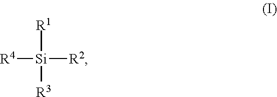

wherein
each of R¹, R², and R³ is independently an alkyl group of C₁ to C₆ or an alkoxy group of C₁ to C₆ with proviso that at least one of R¹, R², and R³ is the alkoxy group of C₁ to C₆, and
R⁴ is an alkyl group of C₁ to C₁₀₀ or a mercaptoalkyl group of C₁ to C₁₀₀.

In accordance with some embodiments of the present disclosure, the plurality of the functionalized molecules are formed using an amino silane-based compound having formulae (II), (III), or (IV)

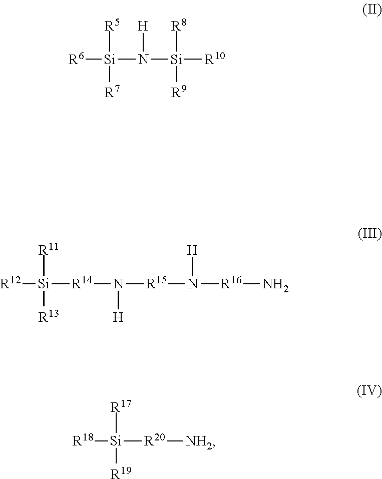

wherein
each of R⁵, R⁶, R⁷, R⁸, R⁹, and R₁₀ is independently an alkyl group of C₁ to C₁₀₀ or a mercaptoalkyl group of C₁ to C₁₀₀,
each of R¹¹, R¹², and R¹³ is independently an alkyl group of C₁ to C₆ or an alkoxy group of C₁ to C₆ with proviso that at least one of R¹¹, R¹², and R¹³ is the alkoxy group of C₁ to C₆,
each of R¹⁴, R¹⁵, and R¹⁶ is independently an alkylene group of C₁ to C₁₀₀,
each of R¹⁷, R¹⁸, and R¹⁹ is independently an alkyl group of C₁ to C₆ or an alkoxy group of C₁ to C₆ with proviso that at least one of R¹⁷, R¹⁸, and R¹⁹ is the alkoxy group of C₁ to C₆, and
R²⁰ is an alkylene group of C₁ to C₁₀₀.

In accordance with some embodiments of the present disclosure, the plurality of the functionalized molecules are formed using a carboxylic acid-based compound has formula (V)

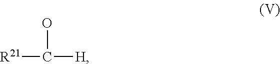

wherein R²¹ is an alkyl group of C₁ to C₁₀₀ or a mercaptoalkyl group of C₁ to C₁₀₀.

In accordance with some embodiments of the present disclosure, a method for manufacturing a semiconductor device includes: forming a conductive interconnect structure over a substrate, the conductive interconnect structure including a plurality of first conductive interconnects spaced apart from each other; forming a dielectric layer over the conductive interconnect structure; forming a plurality of second conductive interconnects which are spaced apart from each other and which protrude upwardly from an upper surface of the dielectric layer, so as to form a plurality of trenches among the plurality of the second conductive interconnects, one of the plurality of the second conductive interconnects penetrating the dielectric layer and being electrically connected to a corresponding one of the plurality of the first conductive interconnects; forming a plurality of functionalized molecules such that the plurality of functionalized molecules are bonded to the upper surface of the dielectric layer so as to form a self-assembled monolayer filled in the plurality of the trenches; subjecting the plurality of the functionalized molecules to a rearrangement treatment so as to permit the plurality of the functionalized molecules to be evenly bonded on the upper surface of the dielectric layer; forming an etch stop layer on the plurality of the second conductive interconnects and the self-assembled monolayer; and removing the self-assembled monolayer to form a plurality of air gaps so that two adjacent ones of the plurality of the second conductive interconnects are spaced apart from each other by a corresponding one of the plurality of the air gaps.

In accordance with some embodiments of the present disclosure, the self-assembled monolayer has a thickness ranging from about 100 Å to about 400 Å.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of first conductive interconnects which are spaced apart from each other and which protrude upwardly from an upper surface of a dielectric layer that is disposed over a substrate, so as to form a plurality of trenches among the plurality of the first conductive interconnects;
forming a plurality of functionalized molecules such that the plurality of functionalized molecule are bonded to the upper surface of the dielectric layer so as to form a self-assembled monolayer filled in the plurality of the trenches;
subjecting the plurality of the functionalized molecules to a rearrangement treatment so as to permit the plurality of the functionalized molecules to be evenly bonded on the upper surface of the dielectric layer;
forming an etch stop layer on the plurality of the first conductive interconnects and the self-assembled monolayer; and
removing the self-assembled monolayer to form a plurality of air gaps so that two adjacent ones of the plurality of the first conductive interconnects are spaced apart from each other by a corresponding one of the plurality of the air gaps.

2. The method as claimed in claim 1, wherein the self-assembled monolayer has an upper end distal from the upper surface of the dielectric layer, each of the plurality of the first conductive interconnects has an upper end distal from the upper surface of the dielectric layer, and the upper end of the self-assembled monolayer is flush with the upper end of each of the plurality of the first conductive interconnects.

3. The method as claimed in claim 2, wherein each of the plurality of the functionalized molecules includes a head group bonded to the upper surface of the dielectric layer and a carbon-based tail group bonded to the head group, the carbon-based tail group having a molecular weight ranging from 15 to 2000.

4. The method as claimed in claim 3, wherein the head group includes a siloxy radical or a carboxyl radical bonded to the upper surface of the dielectric layer.

5. The method as claimed in claim 2, wherein each of the plurality of the air gaps has an upper end distal from the upper surface of the dielectric layer, and the upper end of each of the plurality of the air gaps is flush with the upper end of each of the plurality of the first conductive interconnects.

6. The method as claimed in claim 1, wherein the plurality of the functionalized molecules are formed using a precursor which includes a silane-based compound, an aminosilane-based compound, a carboxylic acid-based compound, or combinations thereof.

7. The method as claimed in claim 6, wherein the silane-based compound has formula (I) 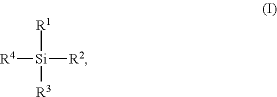
wherein
each of R¹, R², and R³ is independently an aliphatic hydrocarbyl group of C₁ to C₆ or an aliphatic hydrocarbyloxy group of C₁ to C₆ with proviso that at least one of R¹, R², and R³ is the aliphatic hydrocarbyloxy group of C₁ to C₆, and
R⁴ is a hydrocarbyl group of C₁ to C₁₀₀ or a mercaptohydrocarbyl group of C₁ to C₁₀₀.

8. The method as claimed in claim 6, wherein the aminosilane-based compound has formulae (II), (III), or (IV) 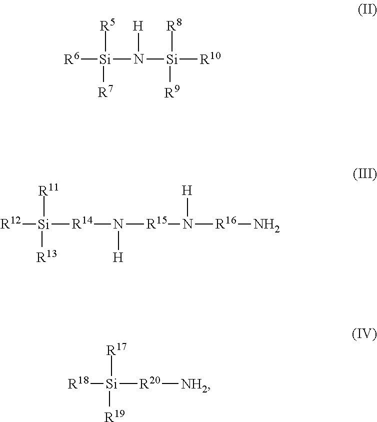
wherein
each of R⁵, R⁶, R⁷, R⁸, R⁹, and R¹⁰ is independently a hydrocarbyl group of C₁ to C₁₀₀ or a mercaptohydrocarbyl group of C₁ to C₁₀₀,
each of R¹¹, R¹², and R¹³ is independently an aliphatic hydrocarbyl group of C₁ to C₆ or an aliphatic hydrocarbyloxy group of C₁ to C₆ with proviso that at least one of R¹¹, R¹², and R¹³ is the aliphatic hydrocarbyloxy group of C₁ to C₆,
each of R¹⁴, R¹⁵, and R¹⁶ is independently a hydrocarbylene group of C₁ to C₁₀₀,
each of R¹⁷, R¹⁸, and R¹⁹ is independently an aliphatic hydrocarbyl group of C₁ to C₆ or an aliphatic hydrocarbyloxy group of C₁ to C₆ with proviso that at least one of R¹⁷, R¹⁸, and R¹⁹ is the aliphatic hydrocarbyloxy group of C₁ to C₆, and
R²⁰ is a hydrocarbylene group of C₁ to C₁₀₀.

9. The method as claimed in claim 6, wherein the carboxylic acid-based compound has formula (V) 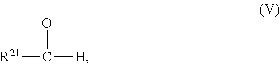
wherein R²¹ is a hydrocarbyl group of C₁ to C₁₀₀ or a mercaptohydrocarbyl group of C₁ to C₁₀₀.

10. The method as claimed in claim 1, wherein the rearrangement treatment is conducted by an annealing process at a temperature ranging from 100° C. to 250° C.

11. The method as claimed in claim 1, wherein the self-assembled monolayer is removed by burning out the plurality of the functionalized molecules at a temperature ranging from 250° C. to 350° C.

12. The method as claimed in claim 1, wherein the etch stop layer has a porosity ranging from 2% to 5%.

13. The method as claimed in claim 1, further comprising forming a conductive interconnect structure over the substrate, the conductive interconnect structure including the dielectric layer and a second conductive interconnect which is disposed in the dielectric layer and which is electrically connected to a corresponding one of the plurality of first conductive interconnects.

14. The method as claimed in claim 1, further comprising forming a conductive interconnect structure between the dielectric layer and the substrate, the conductive interconnect structure including a plurality of second conductive interconnects spaced apart from each other, one of the plurality of the first conductive interconnects penetrating the dielectric layer and being electrically connected to a corresponding one of the plurality of the second conductive interconnects.

15. A method for manufacturing a semiconductor device, comprising:
forming a conductive interconnect structure over a substrate, the conductive interconnect structure including a dielectric layer and a first conductive interconnect disposed in the dielectric layer;
forming a plurality of second conductive interconnects on the conductive interconnect structure, the plurality of the second conductive interconnects being spaced apart from each other so as to form a plurality of trenches among the plurality of the second conductive interconnects, the first conductive interconnect being electrically connected to a corresponding one of the plurality of the second conductive interconnects;
forming a plurality of functionalized molecules such that the plurality of functionalized molecules are bonded to an upper surface of the dielectric layer so as to form a self-assembled monolayer filled in the plurality of the trenches;
subjecting the plurality of the functionalized molecules to a rearrangement treatment so as to permit the plurality of the functionalized molecules to be evenly bonded on the upper surface of the dielectric layer;
forming an etch stop layer on the plurality of the second conductive interconnects and the self-assembled monolayer; and
removing the self-assembled monolayer to form a plurality of air gaps so that two adjacent ones of the plurality of the second conductive interconnects are spaced apart from each other by a corresponding one of the plurality of the air gaps.

16. The method as claimed in claim 15, wherein the plurality of the functionalized molecules are formed using a silane-based compound having formula (I) 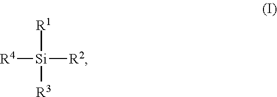
wherein
each of R¹, R², and R³ is independently an alkyl group of C₁ to C₆ or an alkoxy group of C₁ to C₆ with proviso that at least one of R¹, R², and R³ is the alkoxy group of C₁ to C₆, and
R⁴ is an alkyl group of C₁ to C₁₀₀ or a mercaptoalkyl group of C₁ to C₁₀₀.

17. The method as claimed in claim 15, wherein the plurality of the functionalized molecules are formed using an aminosilane-based compound having formulae (II), (III), or (IV) 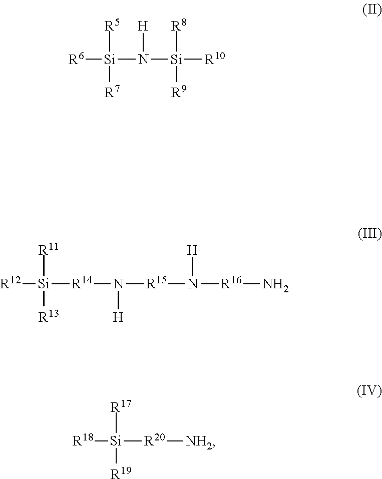
wherein
each of R⁵, R⁶, R⁷, R⁸, R⁹, and R₁₀ is independently an alkyl group of C₁ to C₁₀₀ or a mercaptoalkyl group of C₁ to C₁₀₀,
each of R¹¹, R¹², and R¹³ is independently an alkyl group of C₁ to C₆ or an alkoxy group of C₁ to C₆ with proviso that at least one of R¹¹, R¹², and R¹³ is the alkoxy group of C₁ to C₆,
each of R¹⁴, R¹⁵, and R¹⁶ is independently an alkylene group of C₁ to C₁₀₀,
each of R¹⁷, R¹⁸, and R¹⁹ is independently an alkyl group of C₁ to C₆ or an alkoxy group of C₁ to C₆ with proviso that at least one of R¹⁷, R¹⁸, and R¹⁹ is the alkoxy group of C₁ to C₆, and
R²⁰ is an alkylene group of C₁ to C₁₀₀.

18. The method as claimed in claim 15, wherein the plurality of the functionalized molecules are formed using a carboxylic acid-based compound has formula (V) 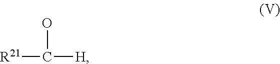
wherein R²¹ is an alkyl group of C₁ to C₁₀₀ or a mercaptoalkyl group of C₁ to C₁₀₀.

19. A method for manufacturing a semiconductor device, comprising:
forming a conductive interconnect structure over a substrate, the conductive interconnect structure including a plurality of first conductive interconnects spaced apart from each other;
forming a dielectric layer over the conductive interconnect structure;
forming a plurality of second conductive interconnects which are spaced apart from each other and which protrude upwardly from an upper surface of the dielectric layer, so as to form a plurality of trenches among the plurality of the second conductive interconnects, one of the plurality of the second conductive interconnects penetrating the dielectric layer and being electrically connected to a corresponding one of the plurality of the first conductive interconnects;
forming a plurality of functionalized molecules such that the plurality of functionalized molecules are bonded to the upper surface of the dielectric layer so as to form a self-assembled monolayer filled in the plurality of the trenches;
subjecting the plurality of the functionalized molecules to a rearrangement treatment so as to permit the plurality of the functionalized molecules to be evenly bonded on the upper surface of the dielectric layer;
forming an etch stop layer on the plurality of the second conductive interconnects and the self-assembled monolayer; and
removing the self-assembled monolayer to form a plurality of air gaps so that two adjacent ones of the plurality of the second conductive interconnects are spaced apart from each other by a corresponding one of the plurality of the air gaps.

20. The method as claimed in claim 19, wherein the self-assembled monolayer has a thickness ranging from 100 Å to 400 Å.
